(19) United States
(12) Patent Application Publication
(10) Pub. No.: US 2007/0044706 A1
(43) Pub. Date: Mar. 1, 2007

(54) Method of forming a crystalline structure and a method of manufacturing a semiconductor device

(75) Inventors: Sung-Kwan Kang, Seoul (KR); Yu-Gyun Shin, Seongnam-si (KR); Jong-Wook Lee, Yongin-si (KR); Yong-Hoon Son, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/509,735

(22) Filed: Aug. 25, 2006

(30) Foreign Application Priority Data
Aug. 26, 2005 (KR) 2005-78552

(51) Int. Cl. C30B 1/00; C30B 28/02; C30B 3/00; C30B 5/00

(52) U.S. Cl. 117/8

(57) ABSTRACT

In a method of forming a single crystalline structure and a method of manufacturing a semiconductor device by using the method of forming the single crystalline structure, a single crystalline seed having elements combining with oxygen to form a network former capable of being easily connected to a network of oxide glass is formed. The single crystalline seed is epitaxially grown to form a single crystalline structure.

### PRIORITY STATEMENT

This application claims benefit of priority under 35 U.S.C. §119 from Korean Patent Application No. 2005-78552 filed on Aug. 26, 2005, the disclosure of which is incorporated herein by reference in its entirety.

### BACKGROUND OF THE INVENTION

1. Field of the Invention

Example embodiments of the present invention relate generally to methods of forming a layered structure, and more particularly to a method of forming a crystalline structure and a method of manufacturing a semiconductor device.

2. Description of the Related Art

A conventional single crystalline structure may be formed on a single crystalline seed by epitaxially growing the single crystalline seed including silicon and/or germanium. However, the silicon and/or the germanium may have a relatively large reactivity with oxygen such that a native oxide layer including oxide may be formed on a surface of the single crystalline seed. If a residue of the native oxide layer remains on the single crystalline seed, the single crystalline structure epitaxially growing from the single crystalline seed may degrade in performance and/or may cause structural deformities. A single crystalline structure formed with such structural deformities or otherwise formed with significant performance degradation may be referred to as a “failed” single crystalline structure or “failure”.

FIG. 1 is a scanning electron microscope (SEM) picture illustrating a native oxide layer residing on a conventional single crystalline seed. Referring to FIG. 1, the native oxide layer may be positioned between the single crystalline seed and a single crystalline structure. The single crystalline structure may have a degraded performance due to the native oxide layer, which in FIG. 1 may take the form of a “line” shaped structural deformity. Also, if the single crystalline seed has a surface defect due to an ion implantation process and/or an etching process, the single crystalline structure epitaxially growing from the single crystalline seed may also degrade in performance due to the surface defect.

FIG. 2 is a SEM picture illustrating a conventional failed single crystalline structure. In FIG. 2, the failure of the single crystalline structure may be due to a surface defect of a single crystalline seed. Referring to FIG 2, a surface of the single crystalline seed may have a surface defect. Thus, a single crystalline structure epitaxially growing from the single crystalline seed may have a failure that may generally take the form of a line.

Thus, conventional single crystalline structures epitaxially growing from a single crystalline seed may fail if the source single crystalline seed includes a surface defect and/or a native oxide layer.

### SUMMARY OF THE INVENTION

Some embodiments of the present invention provide methods of forming a single crystalline structure, the methods being capable of preventing a single crystalline structure from having failures due to surface defects or a native oxide of the single crystalline seed.

Some embodiments of the present invention provide methods of manufacturing a semiconductor device by using the methods of forming the single crystalline structure.

In accordance with some embodiments of the present invention, there are provided methods of forming a single crystalline structure. In the methods, a single crystalline seed having elements combining with oxygen to form a network former capable of being easily connected to a network of oxide glass is formed. The single crystalline seed is epitaxially grown to form a single crystalline structure.

In accordance with some embodiments of the present invention, there are provided methods of manufacturing a semiconductor device. In the methods, a preliminary single crystalline seed is formed. An insulation layer pattern is formed on the preliminary single crystalline seed. The insulation layer pattern has an opening exposing a preliminary contact region of the preliminary single crystalline seed. A single crystalline seed having a contact region is formed by doping elements combining with oxygen to form a network former capable of being easily connected to a network of oxide glass. The contact region is epitaxially grown to form a single crystalline structure filling up the opening.

In accordance with some embodiments of the present invention, there are provided methods of manufacturing a semiconductor device. In the methods, a preliminary single crystalline seed is formed. An insulation layer pattern is formed on the preliminary single crystalline seed. The insulation layer pattern has an opening exposing a preliminary contact region of the preliminary single crystalline seed. A single crystalline seed including the preliminary single crystalline seed and an epitaxial layer is formed. The epitaxial layer is formed by epitaxially growing the preliminary contact region of the preliminary single crystalline seed with doping elements combining with oxygen to form a network former capable of being easily connected to a network of oxide glass into the preliminary contact region. The epitaxial layer is epitaxially grown to form a single crystalline structure filling up the opening.

In accordance with some embodiments of the present invention, there are provided methods of manufacturing a semiconductor device. In the method, a preliminary single crystalline seed is formed. An insulation layer pattern is formed on the preliminary single crystalline seed. The insulation layer pattern has an opening exposing a preliminary contact region of the preliminary single crystalline seed. Elements combining with oxygen to form a network former capable of being easily connected to a network of oxide glass are attached to the preliminary single crystalline seed to form a single crystalline seed including the elements and the preliminary single crystalline seed. The preliminary contact region where the elements are attached is epitaxially grown to form a single crystalline structure.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a scanning electron microscope (SEM) picture illustrating a native oxide layer residing on a conventional single crystalline seed.

FIG. 2 is a SEM picture illustrating a conventional failed single crystalline structure.

FIGS. 3 to 5 are cross-sectional views illustrating a process of forming a single crystalline structure in accordance with an example embodiment of the present invention.

FIGS. 6 and 7 are cross-sectional views illustrating a process of manufacturing a single crystalline structure in accordance with another example embodiment of the present invention.

FIGS. 8 and 9 are cross-sectional views illustrating a process of manufacturing a single crystalline structure in accordance with another example embodiment of the present invention.

FIGS. 10 to 12 are cross-sectional views illustrating a process of manufacturing a semiconductor device in accordance with another example embodiment of the present invention.

FIGS. 13 to 15 are cross-sectional views illustrating a process of manufacturing a semiconductor device in accordance with another example embodiment of the present invention.

FIGS. 16 to 18 are cross-sectional views illustrating a process of manufacturing a semiconductor device in accordance with another example embodiment of the present invention.

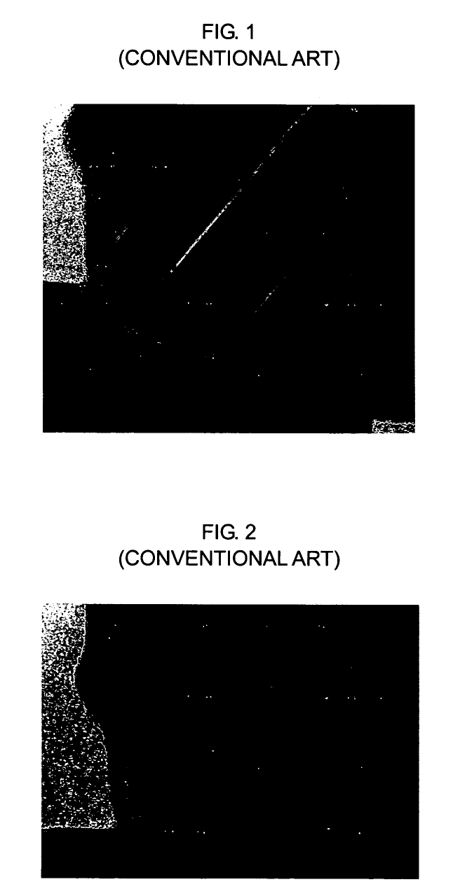

### DETAILED DESCRIPTION OF EXAMPLE EMBODIMENTS OF THE PRESENT INVENTION

Example embodiments of the present invention will be described with reference to the accompanying drawings. The present invention may, however, be embodied in many different forms and should not be construed as limited to the embodiments set forth herein. Rather, example embodiments are provided so that disclosure of the present invention will be thorough and complete, and will fully convey the scope of the present invention to those skilled in the art. The principles and features of this present invention may be employed in varied and numerous example embodiments without departing from the scope of the present invention. In the drawings, the size and relative sizes of layers and regions may be exaggerated for clarity. The drawings are not to scale. Like reference numerals refer to like elements throughout.

It will be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “bellow” and/or “beneath” other elements or features would then be oriented “above” the other elements or features. The device may be otherwise oriented (e.g., rotated 90 degrees or at other orientations) and the spatially relative descriptors used herein interpreted accordingly.

The terminology used herein is for the purpose of describing particular example embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention are described with reference to cross-sectional illustrations that are schematic illustrations of idealized examples of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature of a device and are not intended to limit the scope of the present invention.

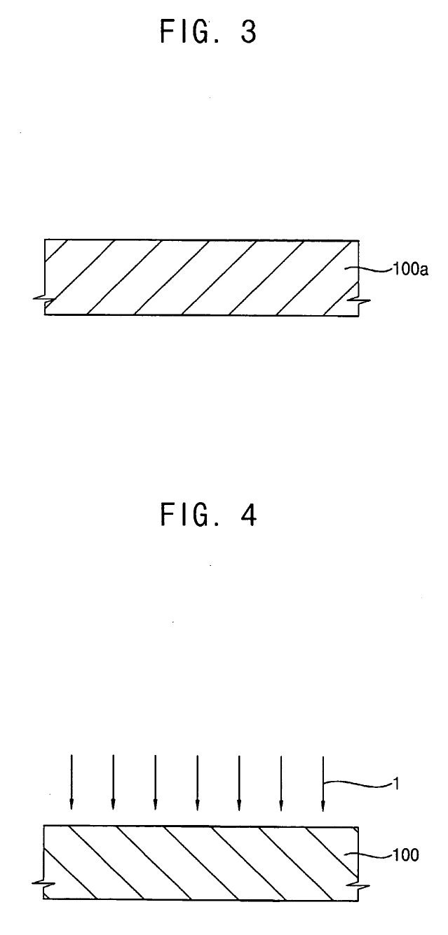

FIGS. 3 to 5 are cross-sectional views illustrating a process of forming a single crystalline structure in accordance with an example embodiment of the present invention.

In the example embodiment of FIG. 3, a preliminary single crystalline seed 100a having a single crystalline state may be prepared. In an example, the preliminary single crystalline seed 100a may include one or more of silicon, germanium and carbon.

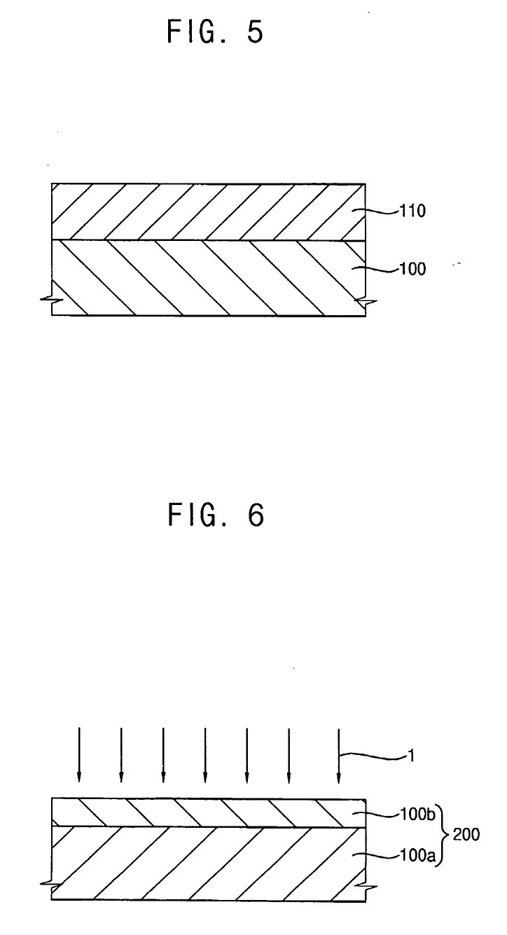

While not illustrated in FIG. 3, a native oxide layer including oxide may be formed on a surface of the preliminary single crystalline seed 100a. If the native oxide layer is not completely removed from the preliminary single crystalline seed 100a, a single crystalline structure 110 (e.g., see FIG. 5 and the description thereof) subsequently formed may have a failure.

In the example embodiment of FIG. 4, an element 1 may be doped into the preliminary single crystalline seed 100a (e.g., with an ion implantation process) to form a single crystalline seed 100. In an example, the element 1 may be combined with oxygen to generate a network former.

In the example embodiment of FIG. 4, the network former may denote an oxide having a structure capable of being combined with a network of oxide glass. In an example, the oxide glass may include silicon oxide (SiO₂). Silicon oxide may have a network structure including SiO₄⁴⁻, which may be embodied as a plurality of inter-connected tetrahedrons. In an example, diphosphorus pentaoxide (P₂O₅) and diboron trioxide (B₂O₃) have structures capable of being combined with the network structure of silicon oxide. Thus, in an example, the element 1 may be phosphorus (P) or boron (B). In a further example, if the element 1 is phosphorus, the network former may be diphosphorus pentaoxide. In an alternative example, if the element 1 is boron, the network former may be diphosphorus pentaoxide.

In the example embodiment of FIG. 4, if the element 1 is phosphorus, phosphorus may be supplied from a phosphine (PH₃) gas. Alternatively, if the element 1 is boron, boron may be supplied from a boron chloride (BCl₃) gas or a diborane (B₂H₆) gas. It is understood that any of the above-described gases may be used either alone or in any combination to supply the element 1.

In the example embodiment of FIG. 4, the element 1 doped into the native oxide layer may react with oxide present within the native oxide layer. This reaction may cause the network former to be formed. For example, if the element 1 is phosphorus, the network former may be diphosphorus pentaoxide. In an alternative example, if the element 1 is boron, the network former may be diboron trioxide. The network former (e.g., diphosphorus pentaoxide, diboron trioxide, etc.) may be reduced by heat. Thus, if the single crystalline seed 100 is formed by doping the element 1 into the preliminary single crystalline seed 100a, the native oxide layer including oxide formed at the surface portion of the preliminary single crystalline seed 100a may be reduced or removed by heating at least the surface portion of the preliminary single crystalline seed 100a.

In an example, referring to FIG. 4, if a doping concentration of the element 1 is substantially below a first doping concentration threshold (e.g., about 1×10¹⁸ EA/Cm³), the native oxide layer may not be reduced sufficiently (e.g., to avoid a failure of an eventual single crystalline structure). Also, if the doping concentration of the element 1 is substantially above the second doping concentration (e.g., about 1×10²⁰ EA/Cm³) the process of doping the element 1 into the preliminary single crystalline seed 100a may damage the preliminary single crystalline seed 100a. Accordingly, the doping concentration of the element 1 may be configured to be between the first and second doping concentration thresholds (e.g., from about 1×10¹⁸ EA/Cm³ to about 10×10²⁰ EA/Cm³).

In the example embodiment of FIG. 5, a surface of the single crystalline seed 100 may be supplied with the source gas such that the single crystalline seed 100 may grow epitaxially. Thus, a single crystalline structure 110 may be formed on the single crystalline seed 100. In an example, the source gas may include a material substantially the same as that included in the preliminary single crystalline seed 100a (e.g., one or more of silicon, germanium, carbon, etc.).

Some elements 1 in the single crystalline seed 100 are exposed on an upper face of the single crystalline seed 100. Thus, numbers of exposed silicon atoms, exposed germanium atoms or exposed carbon atoms that are exposed on the upper face of the single crystalline seed 100 may be substantially smaller.

Particularly, in case that the elements 1 are not doped into the single crystalline seed 100, the upper face of the single crystalline seed 100 may be composed of the silicon atoms, the germanium atoms or the carbon atoms. However, in case that the elements 1 are doped into the single crystalline seed 100, the upper face of the single crystalline seed 100 may be composed of the elements 1 as well as the silicon atoms, the germanium atoms or the carbon atoms. As a result, in case that the elements 1 are doped into the single crystalline seed 100, the numbers of the exposed silicon atoms, the exposed germanium atoms or the exposed carbon atoms may be smaller that the case where the elements 1 are not doped into the single crystalline seed 100.

As described above, the numbers of exposed silicon atoms, exposed germanium atoms or exposed carbon atoms are relatively small. As a result, in case that silicon atoms, germanium atoms or carbon atoms are supplied from the source gas onto the upper face of the single crystalline seed 100, a time required for the silicon atoms, the germanium atoms or the carbon atoms that are supplied from the source gas to move the exposed silicon atoms, the exposed germanium atoms or the exposed carbon atoms in order to be combined with the exposed silicon atoms, the exposed germanium atoms or the exposed carbon atoms is relatively long.

That is, the rearrangement of the silicon atoms, the germanium atoms or the carbon atoms that are supplied from the source gas may require relatively long time. Thus, a lower portion of the single crystalline structure 110 may grow epitaxially from the upper face of the single crystalline seed 100 at a relatively small growth rate.

Because the lower portion of the single crystalline structure 110 epitaxially grows from the upper face of the single crystalline seed 100 at the relatively small growth rate, the lower portion of the single crystalline structure 110 may be relatively dense. Thus, although the single crystalline seed 100 has a surface defect, the single crystalline structure 110 epitaxially growing from the single crystalline seed 100 may hardly have a failure due to the surface defect.

In the example embodiment of FIG. 5, if the single crystalline structure 110 is formed at a temperature below a first temperature threshold (e.g., about 300° C.), then the element 1 (e.g., the silicon atoms, the germanium atoms or the carbon atoms) within the source gas may not be easily separated from the source gas. In an alternative example, if the single crystalline structure 110 is formed at a temperature above about a second temperature threshold (e.g., 1200° C.), it may be easier to separate the element 1 from the source gas, but it may also be more difficult to control a growth rate of the single crystalline structure 110. Thus, in an example, the single crystalline structure 110 may be formed at a temperature between the first and second temperature thresholds (e.g., from about 300° C. to about 1200° C.).

In the example embodiment of FIG. 5, if the single crystalline structure 110 is formed at a pressure below about a first pressure threshold (e.g., 10⁻⁵ Torr), the element 1 (e.g., the silicon atoms, the germanium atoms or the carbon atoms) within the source gas may not be easily separated from the source gas. In an alternative example, if the single crystalline structure 110 is formed at a pressure above a second pressure threshold (e.g., about 760 Torr), it may be easier to separate the element 1 from the source gas, but it may also be more difficult to control a growth rate of the single crystalline structure 110. Thus, in an example, the single crystalline structure 110 may be formed at a pressure between the first and second pressure threshold (e.g., from about 10⁻⁵ Torr to about 760 Torr).

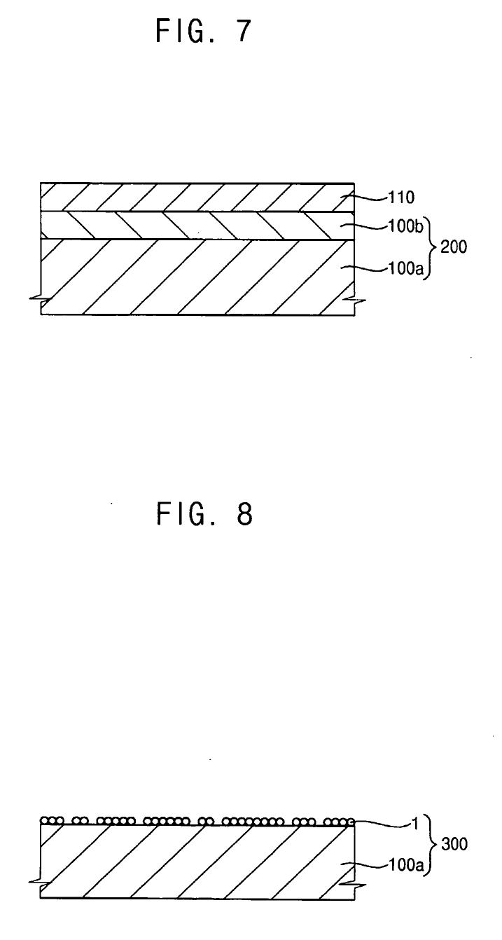

FIGS. 6 and 7 are cross-sectional views illustrating a process of manufacturing a single crystalline structure in accordance with another example embodiment of the present invention. The example process illustrated in FIGS. 6 and 7 is substantially the same as the example process illustrated in FIGS. 3 to 5, except for forming a single crystalline seed 200. Thus, certain identical steps and structural elements will not be described again for the sake of brevity. In addition, the same reference numerals used in FIGS. 6 to 7 may refer to corresponding parts as described above and illustrated in FIGS. 3 to 5.

In the example embodiment of FIG. 6, the element 1, which may be capable of forming a network former, may be doped into the preliminary single crystalline seed 100a while the preliminary single crystalline seed 100a grows epitaxially. Thus, an epitaxial layer 100b may be formed on the preliminary single crystalline seed 100a. That is, the element 1 may be doped into the epitaxial layer 100b with an in-situ doping process.

In the example embodiment of FIG. 6, a single crystalline seed 200 including the preliminary single crystalline seed 100a and the epitaxial layer 100b may be formed. In an example, a lower portion of the single crystalline seed 200 may correspond to the preliminary single crystalline seed 100a and an upper-portion of the single crystalline seed 200 may correspond to the epitaxial layer 100b doped with the element 1.

In the example embodiment of FIG. 6, if a doping concentration of the element 1 is below a first doping concentration threshold (e.g., about 1×10¹⁸ EA/Cm³), the native oxide layer may not be reduced sufficiently (e.g., to avoid a failure of an eventual single crystalline structure). Also, if the doping concentration of the element 1 is above a second doping concentration threshold (e.g., about 1×10²⁰ EA/Cm³), the process of doping the element 1 into the preliminary single crystalline seed 100a may damage the preliminary single crystalline seed 100a. Accordingly, the doping concentration of the element 1 may be configured to be between the first and second doping concentration thresholds (e.g., from about 1×10¹⁸ EA/Cm³ to about 10×10²⁰ EA/Cm³).

In the example embodiment of FIG. 7, a surface of the single crystalline seed 200 may be supplied with a source gas including additional amounts of the element 1 so that the single crystalline seed 200 may epitaxially grow. Thus, a single crystalline structure 110 may be formed on the single crystalline seed 200.

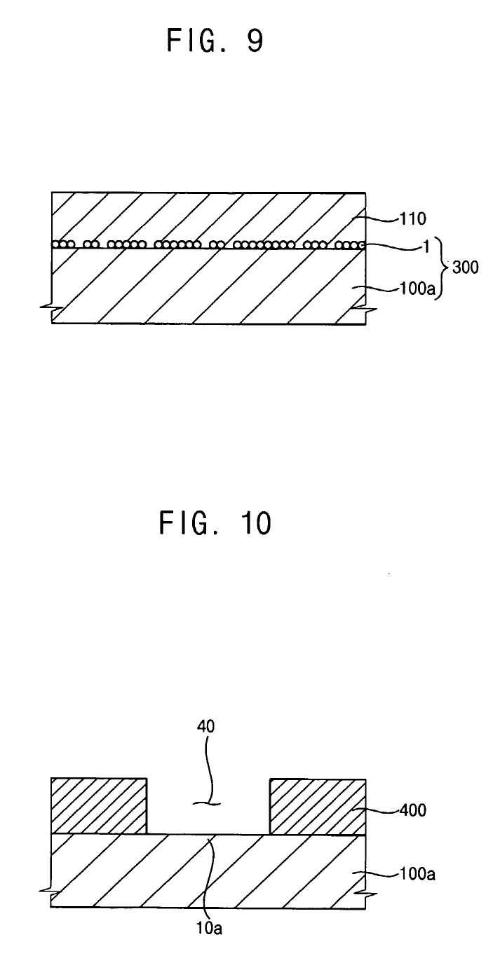

FIGS. 8 and 9 are cross-sectional views illustrating a process of manufacturing a single crystalline structure in accordance with another example embodiment of the present invention. The example process illustrated in FIGS. 8 and 9 is substantially the same as the example processes illustrated in FIGS. 3 to 5 and FIGS. 6 to 7, except for forming a single crystalline seed 300. Thus, certain identical steps and structural elements will not be described again for the sake of brevity. In addition, the same reference numerals used in FIGS. 8 and 9 may refer to corresponding parts as described above and illustrated in FIGS. 3 to 5 and/or FIGS. 6 to 7.

In the example embodiment of FIG. 8, the preliminary single crystalline seed 100a may be supplied with the element 1 so that the element 1 may be attached to a surface of the preliminary single crystalline seed 100a. A single crystalline seed 300 including the preliminary single crystalline seed 100a and the element 1 may thereby be formed. In an example, if the element 1 is phosphorus, the element 1 may be supplied from a phosphine (PH₃) gas. In an alternative example, if the element 1 is boron, the element 1 may be supplied from a boron chloride (BCl₃) gas and/or a diborane (B₂H₆) gas.

In the example embodiment of FIG. 9, a surface of the single crystalline seed 300 may be supplied with a source gas including the element 1 such that the single crystalline seed 300 may epitaxially grow. Thus, a single crystalline structure 110 may be formed on the single crystalline seed 300.

FIGS. 10 to 12 are cross-sectional views illustrating a process of manufacturing a semiconductor device in accordance with another example embodiment of the present invention.

In the example embodiment of FIG. 10, an insulation layer pattern 400 may be formed on a preliminary single crystalline seed 100a. The insulation layer pattern 400 may have an opening 40 exposing a preliminary contact region of the preliminary single crystalline seed 100a. In an example, the insulation layer pattern 400 may include an insulation material such as silicon oxide or silicon nitride.

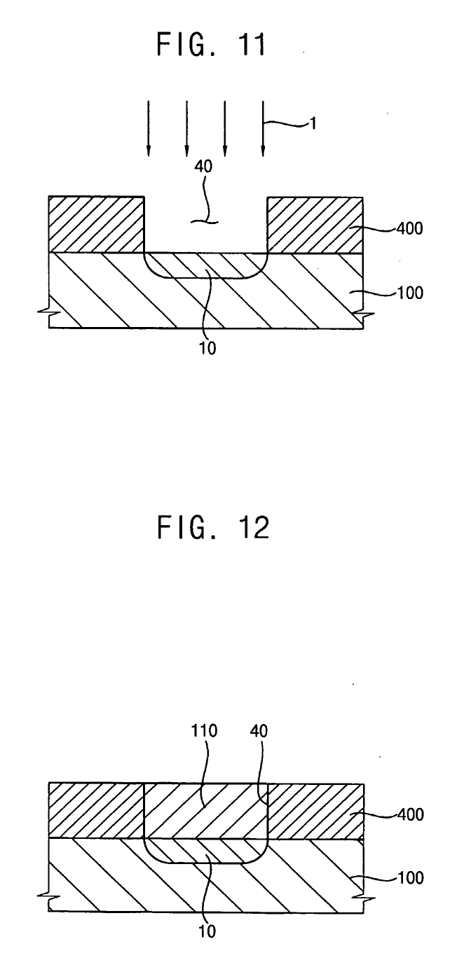

In the example embodiment of FIG. 11, the element 1 may be doped into a preliminary contact region 10a such that a contact region 10 including the element 1 may be formed. In an example, if the element 1 is combined with oxygen, a network former may be formed. Thus, the preliminary single crystalline seed 100a including the preliminary contact region 10a may be changed into the single crystalline seed 100 having the contact region 10. In the example embodiment of FIG. 12, the contact region 10 may epitaxially grow to form a single crystalline structure 10 which may at least partially fill the opening 40.

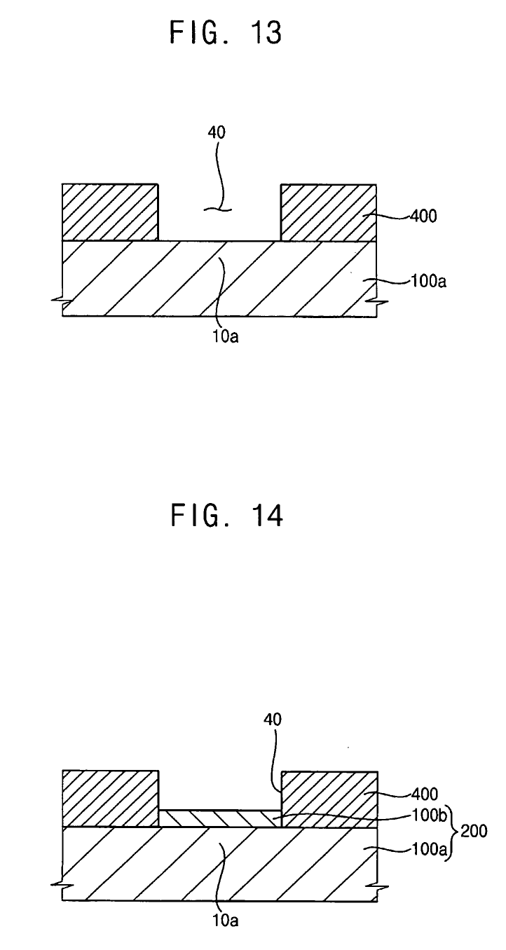

FIGS. 13 to 15 are cross-sectional views illustrating a process of manufacturing a semiconductor device in accordance with another example embodiment of the present invention.

In the example embodiment of FIG. 13, an insulation layer pattern 400 may be formed on a preliminary single crystalline seed 100a. The insulation layer pattern 400 may have an opening 40 exposing a preliminary contact region 10a of the preliminary single crystalline seed 100a. In an example, the insulation layer pattern 400 may include an insulation material such as silicon oxide or silicon nitride.

In the example embodiment of FIG. 14, the element 1, which may be capable of forming a network former, may be doped into the preliminary contact region 10a of the preliminary single crystalline seed 100a such that an epitaxial layer 100b may be formed on the preliminary single crystalline seed 100a In an example, the element 1 may be doped into the epitaxial layer 100b with an in-situ doping process.

In the example embodiment of FIG. 14, a single crystalline seed 200 including a preliminary single crystalline seed 100a and an epitaxial layer 100b may be formed. In an example, a lower portion of the single crystalline seed 200 may correspond to the preliminary single crystalline seed 100a. An upper portion of the single crystalline seed 200 may correspond to the epitaxial layer 100b doped with the element 1. The opening 40 may be partially filled with the epitaxial layer 100b.

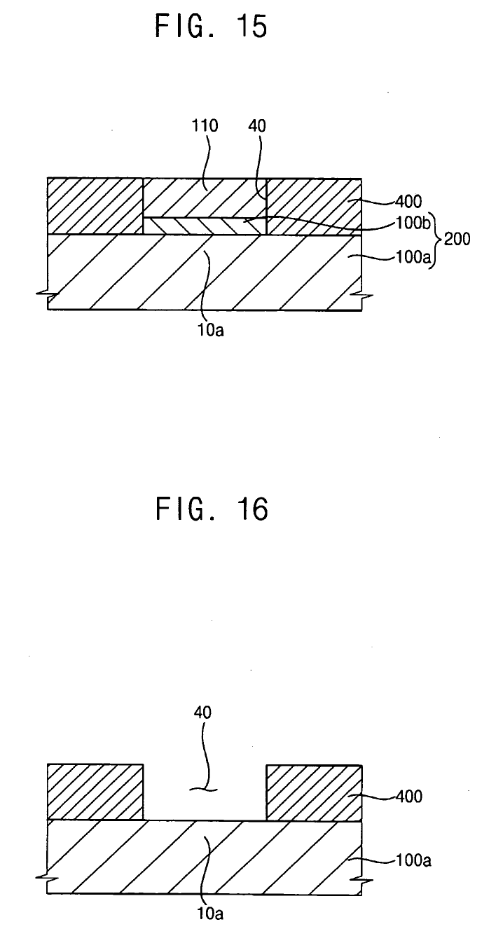

In the example embodiment of FIG. 15, the epitaxial layer 100b may epitaxially grow such that a single crystalline structure filling up the opening 40 may be formed.

FIGS. 16 to 18 are cross-sectional views illustrating a process of manufacturing a semiconductor device in accordance with another example embodiment of the present invention.

In the example embodiment of FIG. 16, an insulation layer pattern 400 may be formed on a preliminary single crystalline seed 100a. The insulation layer pattern 400 may have an opening 40 exposing a preliminary contact region 10a of the preliminary single crystalline seed 100a. In an example, the insulation layer pattern 400 may include an insulation material such as silicon oxide or silicon nitride.

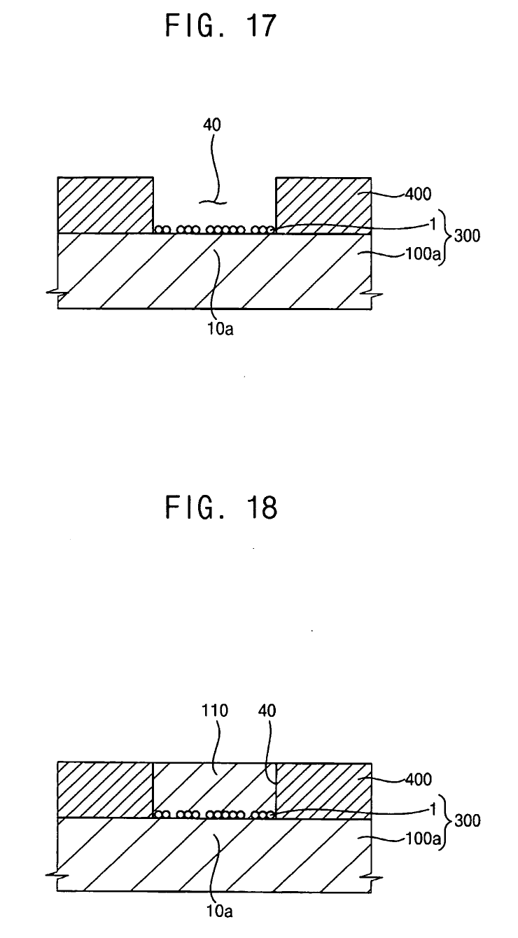

In the example embodiment of FIG. 17, the preliminary contact region 10a of the preliminary single crystalline seed 100a may be supplied with the element 1 such that the element 1 may be attached to a surface of the preliminary contact region 10a. Thus, a single crystalline seed 300 including the preliminary single crystalline seed 100a and the element 1 may be formed. In an example, if the element 1 is phosphorus, the element 1 may be supplied from a phosphine (PH₃) gas. In an alternative example, if the element 1 is boron, the element 1 may be supplied from a boron chloride (BCl₃) gas and/or a diborane (B₂H₆) gas. In the example embodiment of FIG. 18, the single crystalline seed 300 may epitaxially grow such that a single crystalline structure 110 at least partially filling up the opening 40 may be formed.

According to example embodiments of the present invention, a native oxide layer residing on a single crystalline seed may be cleanly removed or reduced. Further, if single crystalline seed has a surface defect, a single crystalline structure epitaxially grown from the single crystalline seed may not be substantially affected by the surface defect.

Example embodiments of the present invention being thus described, it will be obvious that the same may be varied in many ways. For example, while the application of element 1 is above-described as being applied by doping, in-situ doping, supplied from a gas which causes the element 1 to be attached by maintaining an operating environment in a given temperature and pressure range, attaching the element 1 to a surface, etc., it will be readily apparently that the element 1 may be applied in any well-known manner such that a network former may be formed.

Further, the term “element” as used above is intended to encompass both elements and compounds, and as such is not necessarily limited to a “single” element, such as boron or phosphorous.

Such variations are not to be regarded as a departure from the spirit and scope of example embodiments of the present invention, and all such modifications as would be obvious to one skilled in the art are intended to be included within the scope of the following claims.

What is claimed is:

1. A method of forming a single crystalline structure, the method comprising:
forming a single crystalline seed having elements combining with oxygen to form a network former capable of being easily connected to a network of oxide glass; and
epitaxially growing the single crystalline seed to form a single crystalline structure.

2. The method of claim 1, wherein the element is phosphorus.

3. The method of claim 2, wherein the phosphorus is supplied from a phosphine gas.

4. The method of claim 1, wherein the elements is boron.

5. The method of claim 4, wherein the boron is supplied from at least one gas selected from the group consisting of a boron chloride gas and a diborane gas.

6. The method of claim 1, wherein the single crystalline seed includes at least one material selected from the group consisting of silicon, germanium and carbon.

7. The method of claim 1, wherein forming the single crystalline seed comprises:
forming a preliminary single crystalline seed; and
doping the element into the preliminary single crystalline seed by using an ion implantation process.

8. The method of claim 7, wherein a doping concentration of the element is about 1×10¹⁸ EA/Cm³ to about 1×10²⁰ EA/Cm³.

9. The method of claim 1, wherein forming the single crystalline seed comprises:
forming a preliminary single crystalline seed; and
doping the element into the preliminary single crystalline seed by an in-situ doping process in epitaxially growing the preliminary single crystalline seed.

10. The method of claim 9, wherein a doping concentration of the element is about 1×10¹⁸ EA/Cm³ to about 1×10²⁰ EA/Cm³.

11. The method of claim 1, wherein forming the single crystalline seed comprises:
forming a preliminary single crystalline seed; and
attaching the elements to a surface of the preliminary single crystalline seed.

12. A method of manufacturing a semiconductor device, the method comprising:
forming a preliminary single crystalline seed;
forming an insulation layer pattern on the preliminary single crystalline seed, the insulation layer pattern having an opening exposing a preliminary contact region of the preliminary single crystalline seed;
forming a single crystalline seed having a contact region formed by doping elements combining with oxygen to form a network former capable of being easily connected to a network of oxide glass; and
epitaxially growing the contact region to form a single crystalline structure filling up the opening.

13. A method of manufacturing a semiconductor device, the method comprising:
forming a preliminary single crystalline seed;
forming an insulation layer pattern on the preliminary single crystalline seed, the insulation layer pattern having an opening exposing a preliminary contact region of the preliminary single crystalline seed;
forming a single crystalline seed including the preliminary single crystalline seed and an epitaxial layer, the epitaxial layer being formed by epitaxially growing the preliminary contact region of the preliminary single crystalline seed with doping elements combining with oxygen to form a network former capable of being easily connected to a network of oxide glass into the preliminary contact region; and
epitaxially growing the epitaxial layer to form a single crystalline structure filling up the opening.

14. A method of manufacturing a semiconductor device, the method comprising:
forming a preliminary single crystalline seed;
forming an insulation layer pattern on the preliminary single crystalline seed, the insulation layer pattern having an opening exposing a preliminary contact region of the preliminary single crystalline seed;
attaching elements combining with oxygen to form a network former capable of being easily connected to a network of oxide glass to the preliminary single crystalline seed to form a single crystalline seed including the elements and the preliminary single crystalline seed; and
epitaxially growing the preliminary contact region where the elements are attached to form a single crystalline structure filling up the opening.
